(19) United States
(12) Patent Application Publication
(10) Pub. No.: US 2008/0163816 A1
(43) Pub. Date: Jul. 10, 2008

(54) Apparatus For Forming Thin Film

(76) Inventors: Masayuki Toda, Yonezawa-shi (JP); Masaki Kusuhara, Tokyo (JP)

Correspondence Address: YOUNG & THOMPSON, 209 Madison Street, Suite 500, ALEXANDRIA, VA, 22314, US

(21) Appl. No.: 10/569,138

(22) PCT Filed: Aug. 23, 2004
(86) PCT No.: PCT/JP04/12072

§ 371 Date: May 22, 2006

(30) Foreign Application Priority Data
Aug. 22, 2003 (JP) 2003-298830

(51) Int. Cl. C23C 16/00

(52) U.S. Cl. 118/715

(57) ABSTRACT

Disclosed is an apparatus for forming a thin film which contributes to uniformize the film pressure of a film formed on a substrate. A shower nozzle (15) is provided with a peripheral wall (15c) which stands on the opening edge of an outer wall (15a). The shower nozzle (15) is supplied with a raw material gas via a pipe (14) which gas is vaporized by a vaporizer (11), and sprays the raw material gas onto a substrate (P) which is arranged opposite to a nozzle surface (15b) for formation of a film.

### TECHNICAL FIELD

The present invention relates to a thin-film forming apparatus in which a solution in which an organometallic compound or an organometallic complex compound is dissolved in an organic solvent is vaporized, and the yielded gas is supplied onto a substrate on which a film is to be formed, by which a film is formed by chemical vapor deposition.

### BACKGROUND ART

Patent Document 1: Unexamined Japanese Patent Publication No. 2002-305194

In recent years, in the field of electronic device, as the circuit density increases, smaller size and higher performance of electronic device have further been demanded. For example, like SRAM (Static Random Access read write Memory) in which storage operation of information is performed by a combination of transistors, EEPROM (Electrically Erasable and Programmable Read Only Memory), or DRAM (Dynamic Random Access Memory) in which storage operation of information is performed by a combination of transistors and capacitors, not only the fulfillment of function of electronic device achieved simply by a circuit configuration only but also the fulfillment of function of device achieved by utilizing the characteristics of the material itself such as a functional thin film has become advantageous.

Therefore, a dielectric material used for an electronic part is desired to be made a thin film. One method for making such a material a thin film is the CVD process.

This CVD process has features of a film forming rate higher than that of the PVD process, sol-gel process, and other film forming methods, easy manufacture of multilayer thin film, and the like. Also, the MOCVD process is a CVD process in which a compound containing an organic substance is used as a raw material, and has advantages of high safety, no mixture of halide in a film, and the like.

The material used for the MOCVD process is generally solid powder or liquid. In this process, the material is put in a vessel, and is generally heated at a reduced pressure and vaporized in a vaporizer, and thereafter is sent into a thin-film forming chamber by a carrier gas.

FIG. 2 is a schematic explanatory view of a thin-film forming apparatus used in the MOCVD process.

In FIG. 2, reference numeral 1 denotes a vaporizer, 2 denotes a combustion chamber, 3 denotes a reaction vessel, 4 denotes a pipe, and 5 denotes a substantially conical shower nozzle.

In the vaporizer 1, a mixed raw material in which a plurality of kinds (Ba, Sr, Ti) of liquid raw materials pressurized by He gas are mixed in a desired ratio is transported into the vaporizer 1 at a fixed velocity, and the raw material is vaporized while the flow rate thereof is controlled. The vaporization conditions were set so that the preset temperature is 250° C. and the vaporization pressure is 2 kPa. The source gas vaporized in the vaporizer 1 is mixed with Ar, which is a carrier gas, and is introduced into the combustion chamber 2 through a pipe heated to a temperature of 250 to 260° C.

The combustion chamber 2 has a construction such that the source gas is mixed with oxygen, and the mixed gas is heated while flowing in a thin tube preset at a desired temperature. The source gas coming out of the combustion chamber 2 passes through the pipe 4 heated to a temperature of 260 to 270° C. and the shower nozzle 5, and is introduced into the reaction vessel 3. In the combustion chamber 2, the temperature is set at a temperature at which at least some of an organic solvent in the source gas burns.

In the shower nozzle 5, oxygen can be mixed with the source gas as necessary. A substrate P, which is arranged opposedly to the shower nozzle 5 with a predetermined clearance provided therebetween, on which a dielectric film is formed is placed on an aluminum nitride-made susceptor 6, and is heated by a heater 7. The susceptor 6 is mounted with a thermocouple, so that feedback control due to thermocouple indicated value and temperature control due to electric power applied to the heater 7 can be carried out.

The source gas vaporized in the vaporizer 1 is mixed in the combustion chamber 2, and is introduced into the reaction vessel 3 through the shower nozzle 5, by which a dielectric film is formed on the substrate P.

### DISCLOSURE OF THE INVENTION

### Problems to be Solved by the Invention

In the thin-film forming apparatus constructed as described above, since the shower nozzle 5 is simply open (conical shape or pyramid shape) from the introduction port thereof with the pipe 4 being the center, the flow velocity of source gas differs between in a portion near the center of the nozzle surface and in a portion near the end thereof, so that a difference in pressure of source gas is produced when the source gas is introduced from the nozzle surface into the reaction vessel 3 (indicated by the length of arrow mark in FIG. 2).

This pressure difference becomes a difference in film pressure of the dielectric film formed on the substrate P, so that there arises a problem in that a dielectric film having a uniform film pressure cannot be formed on the substrate P.

The present invention has been made to solve the above problem, and accordingly an object thereof is to provide a thin-film forming apparatus capable of contributing to uniformizing the film pressure of a film formed on a substrate.

### Means for Solving the Problems

To achieve the above object, a thin-film forming apparatus described in claim 1 is characterized in that in a thin-film forming apparatus including a shower nozzle which is supplied with a source gas, which is vaporized by a vaporizer, via a pipe, and sprays the source gas onto a substrate on which a film is to be formed, which is arranged opposedly to a nozzle surface, the shower nozzle is made up of an outer wall which is open with the introduction port of the pipe being the center, a peripheral wall erecting at the opening edge of the outer wall, and the nozzle surface covering the end portion of the peripheral wall.

A thin-film forming apparatus described in claim 2 is characterized in that the height of the peripheral wall is greater than a half of the height from the introduction port of the pipe to the nozzle surface.

A shower nozzle described in claim 3 is characterized in that a shower nozzle which is supplied with a source gas, which is vaporized by a vaporizer, and sprays the source gas onto a substrate on which a film is to be formed is characterized by being made up of an outer wall which is open with the introduction port of the pipe being the center, a peripheral wall erecting at the opening edge of the outer wall, and a nozzle surface covering the end portion of the peripheral wall.

A thin-film forming apparatus for MOCVD described in claim 4 is characterized by being provided with the thin-film forming apparatus or the shower nozzle according to claims 1 to 3.

### ADVANTAGES OF THE INVENTION

In the thin-film forming apparatus in accordance with the present invention, since the peripheral wall is provided on the shower nozzle, a difference in flow velocity of source gas in the shower nozzle caused by the shape of outer wall can be decreased, which contributes to uniformizing the film pressure of a film formed on a substrate.

Also, since the height of peripheral wall is set so as to be greater than a half of the height from the introduction port of the pipe to the nozzle surface, the difference in flow velocity of source gas in the shower nozzle can be decreased more surely.

### BRIEF DESCRIPTION OF THE DRAWINGS

FIG. 1 is views of a thin-film forming apparatus used for the MOCVD process in accordance with the present invention, FIG. 1(A) being a schematic explanatory view of the thin-film forming apparatus, and FIG. 1(B) being a explanatory view of an essential portion of a modification of the thin-film forming apparatus; and

FIG. 2 is a schematic explanatory view of a conventional thin-film forming apparatus used for the MOCVD process.

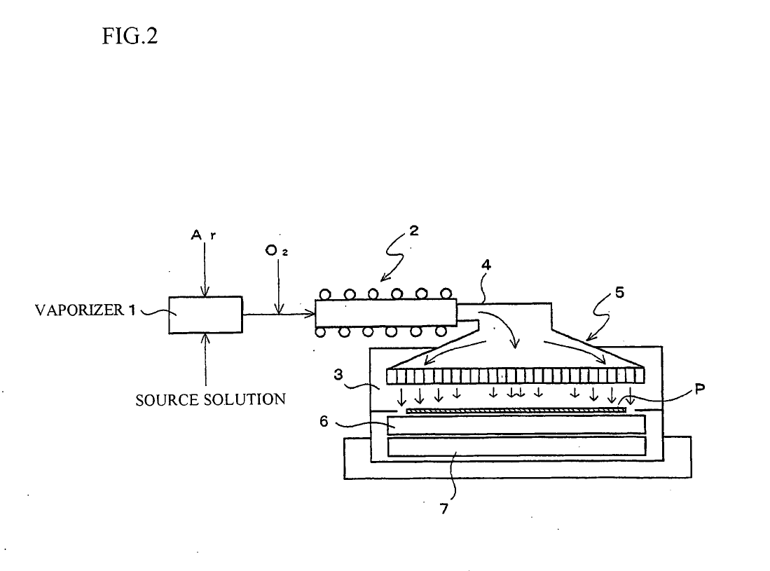

### EXPLANATION OF SYMBOLS

11 . . . vaporizer
12 . . . heater
13 . . . reaction vessel
14 . . . pipe
15 . . . shower nozzle
15a . . . outer wall
15b . . . nozzle surface
15c . . . peripheral wall

### BEST MODE FOR CARRYING OUT THE INVENTION

A thin-film forming apparatus in accordance with the present invention will now be described with reference to the accompanying drawings.

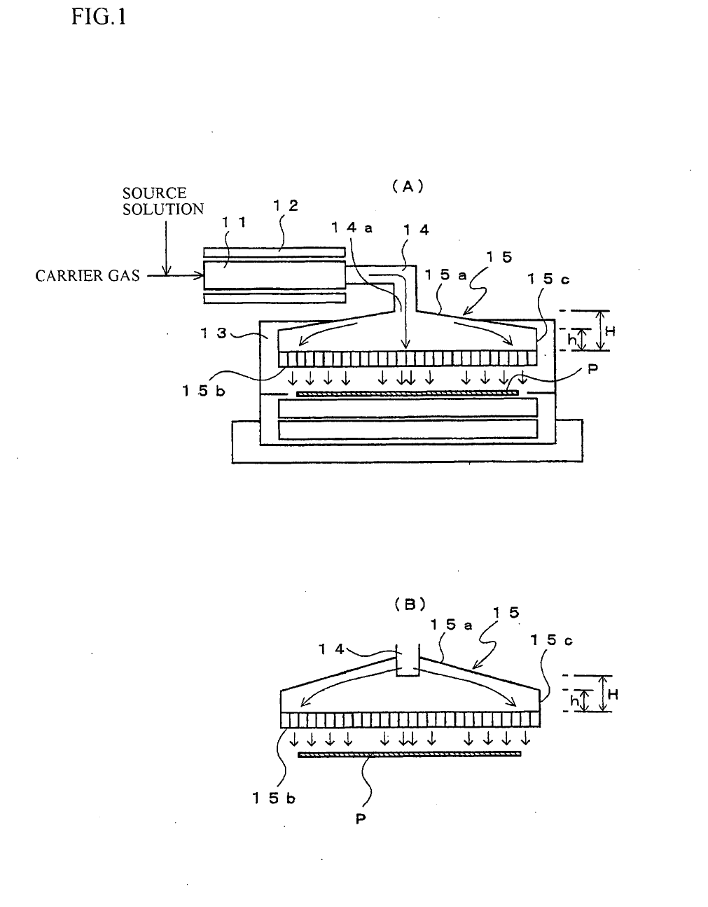

In FIG. 1(A), reference numeral 11 denotes a vaporizer, 12 denotes a heater, 13 denotes a reaction vessel, 14 denotes a pipe, and 15 denotes a substantially conical shower nozzle.

In the vaporizer 11, a mixed raw material in which a plurality of kinds (Ta, Sr, Bi, etc.) of liquid raw materials pressurized by a carrier gas (Ar+O2 or N2+O2) are mixed in a desired ratio is transported into the vaporizer 11 at a fixed velocity, and the raw material is vaporized while the flow rate thereof is controlled. The carrier gas vaporized in the vaporizer 11 is introduced to the shower nozzle 15 through the pipe 14.

In the shower nozzle 15, oxygen can be mixed with the source gas as necessary. A substrate P on which a dielectric film is to be formed is arranged in the reaction vessel 13 opposedly to the shower nozzle 15 with a predetermined clearance provided therebetween. Also, the shower nozzle 15 is configured so that a peripheral wall 15c is integrally provided between an outer wall 15a that is open from the center thereof and a nozzle surface 15b.

This peripheral wall 15, which is provided to secure the distance between the outer wall 15a and the nozzle surface 15b, can decrease the difference in flow velocity of source gas between in a portion near the center of the nozzle surface 15b and in a portion near the end thereof. The height h of the peripheral wall 15c is preferably greater than the maximum height of shower nozzle 15, that is, a half of the height H from an introduction port 14a of the pipe 14 to the center of the nozzle surface 15b (h>H/2).

Thereby, when the carrier gas vaporized in the vaporizer 11 is introduced into the reaction vessel 13 through the shower nozzle 15, the difference in flow velocity of source gas between in a portion near the center of the nozzle surface 15b and in a portion near the end thereof is decreased, and therefore the difference in pressure of source gas produced when the source gas is introduced from the nozzle surface 15b into the reaction vessel 13 is decreased (indicated by the length of arrow mark in FIG. 1), by which a substantially uniform dielectric film can be formed on the substrate P.

In the above-described example, there is disclosed the thin-film forming apparatus in which the shower nozzle 15 is integrally continuous to the pipe 14. However, for example, as shown in FIG. 1(B), the shower nozzle 15 may be connected to the pipe 14 at a position higher than the tip end of the pipe 14.

### INDUSTRIAL APPLICABILITY

In the thin-film forming apparatus in accordance with the present invention, since the peripheral wall is provided on the shower nozzle, the difference in flow velocity of source gas in the shower nozzle caused by the shape of outer wall can be decreased, which contributes to uniformizing the film pressure of a film formed on a substrate.

Also, since the height of peripheral wall is set so as to be greater than a half of the height from the introduction port of the pipe to the nozzle surface, the difference in flow velocity of source gas in the shower nozzle can be decreased more surely.

1. A thin-film forming apparatus comprising a shower nozzle which is supplied with a source gas, which is vaporized by a vaporizer, via a pipe, and sprays the source gas onto a substrate on which a film is to be formed, which is arranged opposedly to a nozzle surface, characterized in that
the shower nozzle is made up of an outer wall which is open with the introduction port of the pipe being the center, a peripheral wall erecting at the opening edge of the outer wall, and the nozzle surface covering the end portion of the peripheral wall.

2. The thin-film forming apparatus according to claim 1, characterized in that the height of the peripheral wall is greater than a half of the height from the introduction port of the pipe to the nozzle surface.

3. A shower nozzle which is supplied with a source gas, which is vaporized by a vaporizer, and sprays the source gas onto a substrate on which a film is to be formed, characterized by
being made up of an outer wall which is open with the introduction port of the pipe being the center, a peripheral wall erecting at the opening edge of the outer wall, and a nozzle surface covering the end portion of the peripheral wall.

4. A thin-film forming apparatus for MOCVD characterized by being provided with the thin-film forming apparatus or the shower nozzle according to claim 1.

5. A thin-film forming apparatus for MOCVD characterized by being provided with the thin-film forming apparatus or the shower nozzle according to claim 2.

6. A thin-film forming apparatus for MOCVD characterized by being provided with the thin-film forming apparatus or the shower nozzle according to claim 3.
